(19) United States
(12) Patent Application Publication
(10) Pub. No.: US 2008/0299688 A1
(43) Pub. Date: Dec. 4, 2008

(54) METHOD OF BONDING A SOLDER TYPE LIGHT EMITTING DIODE CHIP

(76) Inventor: Pei-Choa WANG, Gueishan Township (TW)

Correspondence Address: HDSL, P.O. BOX 220746, CHANTILLY, VA, 20153-0746, US

(21) Appl. No.: 11/757,361

(22) Filed: Jun. 2, 2007

(51) Int. Cl. H01L 33/00

(52) U.S. Cl. 438/26; 257/E33.075; 257/E33.057

(57) ABSTRACT

In a method of bonding a low-resistance solder type light emitting diode chip, a copper substrate is prepared; an insulating layer is coated on the copper substrate; a conductive layer is formed on the insulating layer; a solder paste is coated onto the conductive layer by silk screen printing; a the chip is placed on the conductive layer and heated to melt the solder paste coated between the conductive layer and the chip; and finally the copper substrate is cooled such that the solder paste forms a solder layer to mount the chip onto the conductive layer.

### BACKGROUND OF THE INVENTION

1. Field of the Invention

The present invention relates to a light emitting diode (LED), and more particular to a method of bonding a light emitting diode chip.

2. Description of Prior Art

Light emitting diode comes with the advantages of a compact size, a long life expectancy, a low power consumption, a quick response rate, and a shockproof feature, and thus it is widely used as a light emitting component for various different electric appliances, information billboards, and communication products.

At present, there are different types of light emitting diodes, which can be divided into high-brightness light emitting diodes and moderate-brightness emitting diodes according to the level of brightness. High-brightness light emitting diodes are light emitting diodes made of quaternary compounds and GaN series compounds and moderate-brightness light emitting diodes are light emitting diodes made of binary compounds and ternary compounds other than the GaN series compounds. Since high-brightness light emitting diodes produce tremendous heat energy during their operations, therefore it is necessary to install a heat sink on the circuit substrate of each high-brightness light emitting diode or a heat slug on the lead frame, so that a heat dissipating mechanism can conduct the heat energy produced by the high-brightness light emitting diode chip to the heat sink or heat slug for the heat dissipation to extend the life expectancy of the high-brightness light emitting diodes.

However, traditional high-brightness light emitting diodes generally come with a low heat conductivity, since a silver paste is used for bonding a chip onto a conductive layer or a lead frame of the substrate when the high-brightness light emitting diode is bonded, and the thermal resistance of the silver paste is relatively high. As a result, it is difficult to control the thickness of the silver paste coated onto the conductive layer or the lead frame by a dispersion method and thus adversely affecting the conduction of the heat produced by the chip.

### SUMMARY OF THE INVENTION

In view of the foregoing shortcomings of the prior art, the inventor of the present invention based on years of experience in the related industry to conduct experiments and modifications, and finally invented a method of bonding a light emitting diode chip in accordance with the present invention.

Therefore, it is a primary objective of the present invention to provide a method of die bonding a solder type light emitting diode by using a solder with a low thermal resistance and controlling the solder thickness in a range of 4˜5 μm to enhance the effect of heat conduction.

To achieve the foregoing objective, the present invention provides a method of die bonding a solder type light emitting diode, and the method comprises the steps of: preparing a copper substrate; forming an insulating layer on a surface of the copper substrate; forming a conductive layer on the insulating layer; coating a solder paste onto the conductive layer by silk screen printing; placing the chip on the conductive layer; heating and melting the solder paste coated between the conductive layer and the chip, and finally cooling the copper substrate, such that the solder paste forms a thin film solder layer for bonding the chip on the conductive layer.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a flow chart of die boding a light emitting diode in accordance with the present invention;

FIG. 2 is a schematic view of an insulating layer formed on a copper substrate in accordance with the present invention;

FIG. 3 is a schematic view of a conductive layer formed on an insulating layer in accordance with the present invention;

FIG. 4 is a schematic view of a solder paste applied on a conductive layer in accordance with the present invention;

FIG. 5 is a schematic view of a solder paste placed on a chip in accordance with the present invention; and

FIG. 6 is a side view of a substrate of the present invention.

### DETAILED DESCRIPTION OF THE INVENTION

The technical characteristics, features and advantages of the present invention will become apparent in the following detailed description of the preferred embodiments with reference to the accompanying drawings. The drawings are provided for reference and illustration only, but not intended for limiting the present invention.

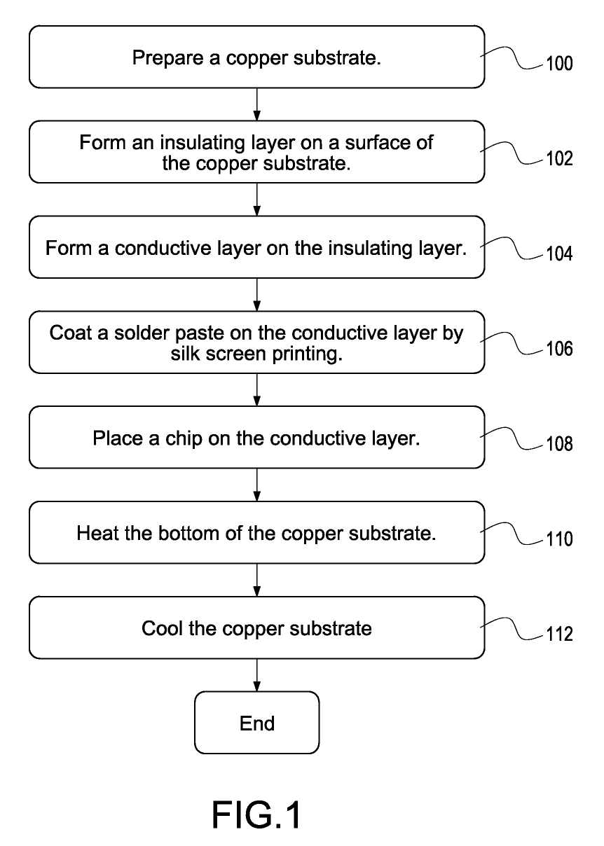

Referring to FIG. 1 for a flow chart of die bonding a light emitting diode in accordance with the present invention, and a method of die bonding a solder type light emitting diode comprises the following steps:

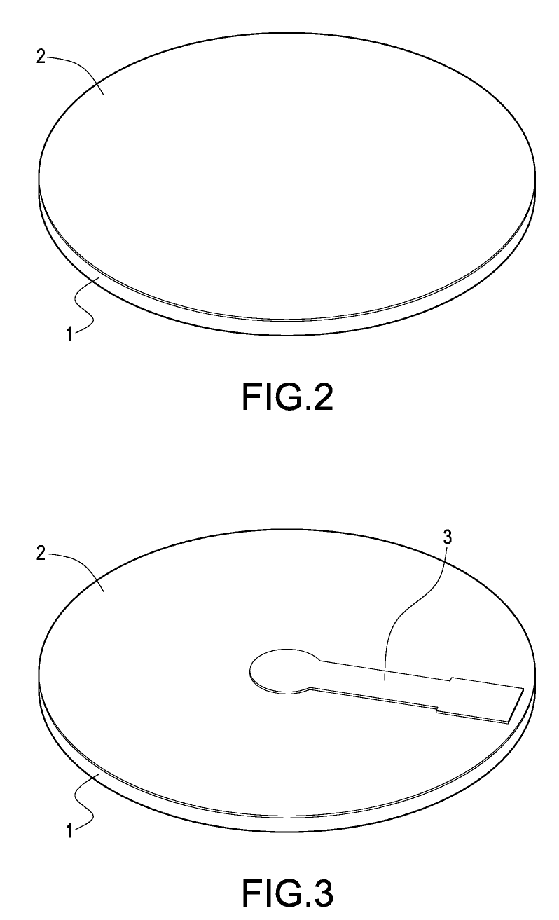

In Step 100, a copper substrate 1 as shown in FIG. 2 is prepared.

In Step 102, an insulating layer 2 is formed on a surface of the copper substrate 1. In the figure, the insulating layer is made of a thermal insulating material.

In Step 104, a conductive layer 3 is formed on the insulating layer as shown in FIG. 3.

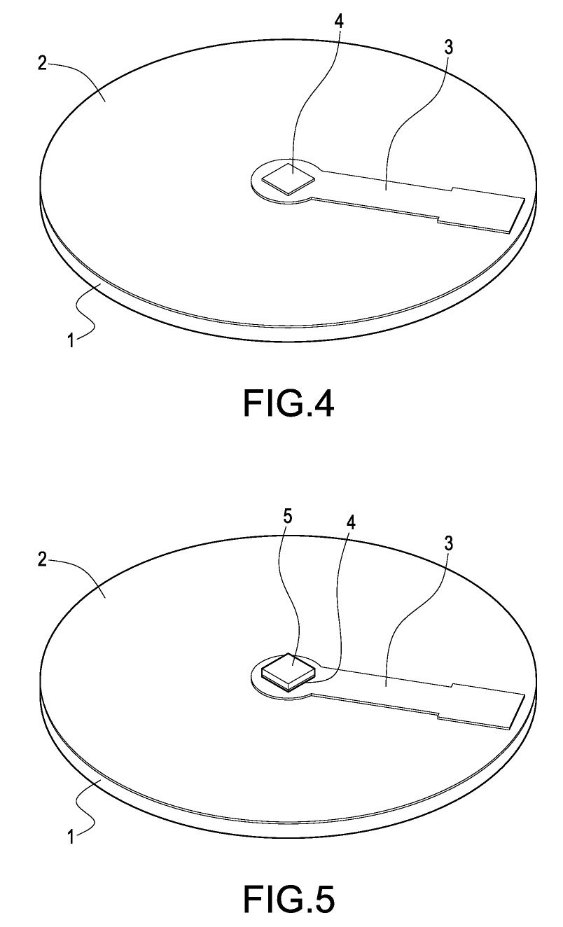

In Step 106, a solder paste 4 is coated at a predetermined bonding position on the conductive layer 3 by silk screen printing as shown in FIG. 4.

In Step 108, a light emitting diode chip 5 is placed on the conductive layer 3 as shown in FIG. 5.

In Step 110, the bottom of the copper substrate 1 is heated to melt the solder paste 4 coated between the conductive layer 3 and the chip 5.

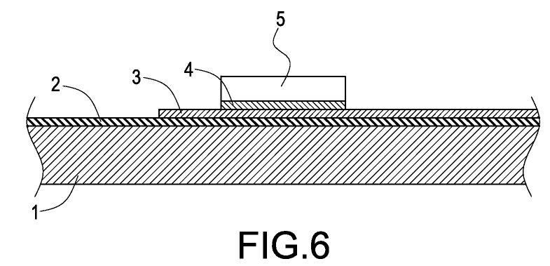

In Step 112, the copper substrate 1 is cooled, so that the solder paste 4 forms a thin film solder layer to bond the chip 5 on the conductive layer 3 as shown in FIG. 6.

During the foregoing fabrication process, the quantity of solder paste coated onto the conductive layer 3 can be controlled by the mesh size of a silk screen. After the heating and cooling processes, the solder layer bonds the chip 5 on the conductive layer 3, and the thickness of the solder layer can be controlled in a range of 4˜5 μm. In addition, the thermal resistance of the solder paste 4 is smaller than that of a conventional silver paste, and thus the heat produced by the chip 5 can be conducted rapidly to the copper substrate 1 for the heat dissipation.

The present invention is illustrated with reference to the preferred embodiments and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method of bonding a solder type light emitting diode chip, comprising the steps of:
(a) preparing a copper substrate;
(b) forming an insulating layer on a surface of the copper substrate;
(c) forming a conductive layer on the insulating layer;
(d) coating a solder paste onto a predetermined position of the chip on the conductive layer by silk screen printing;
(e) placing the chip on the coated solder paste;
(f) heating and melting the solder paste to form a thin film of solder layer; and
(g) cooling the copper substrate.

2. The method of bonding a solder type light emitting diode chip as recited in claim 1, wherein the insulating layer is a thermal insulator.

3. The method of bonding a solder type light emitting diode chip as recited in claim 1, wherein the solder layer has a thickness of 4˜5 μm.
